(19) United States
(12) Patent Application Publication
(10) Pub. No.: US 2011/0132429 A1
(43) Pub. Date: Jun. 9, 2011

(54) System and method for the use of waste heat

(76) Inventor: Jay Stephen Kaufman, Kingston, NH (US)

(21) Appl. No.: 12/592,826

(22) Filed: Dec. 3, 2009

(51) Int. Cl. H01L 31/042; F25J 1/00; F25J 3/00; F17C 9/02; F24J 2/30; B01J 12/00

(52) U.S. Cl. 136/246; 62/615; 62/640; 62/50.2; 126/643; 422/187

(57) ABSTRACT

A system for using the waste heat produced from the production of liquefied or solidified heat sink refrigerant in the production of fuel that includes a liquefied or solidified heat sink refrigerant production system, a fuel production system, and a heat exchanger. The liquefied or solidified heat sink refrigerant production system produces waste heat which is transferred through the heat exchanger to power the fuel production system

### FIELD OF THE INVENTION

The present invention relates to the production of fuels and, in particular to systems for using waste heat from the production of liquefied or solidified heat sink refrigerant for an engine in the production of fuel.

### BACKGROUND OF THE INVENTION

This country, and indeed the world, is currently highly dependent on the use of fossil fuels for such common uses as motor vehicle engines, home environmental controls, and industrial manufacturing. As fossil fuels are consumed more rapidly than they can be produced, we are amidst a so-called “energy crisis.” As such, there is a widely recognized need to develop new technologies to harness energy other than that gained from fossil fuel consumption. Moreover, as the burning of fossil fuels produces byproducts that are both unhealthy for individual persons and dangerous for the environment, technologies that use “clean” energy sources, or energy sources that do not produce unhealthy or dangerous byproducts upon consumption, are also in high demand. Finally, warnings of the steady increase in temperature of the earth's atmosphere, or “greenhouse effect,” advise the development of energy technology that minimizes the release of heat from the technology's operation, or “waste heat.”

Examples of such technologies abound. Common examples of technologies that exploit natural “clean” energy sources include photo-voltaic panels for capturing solar energy, wind turbines for harnessing wind energy, and geothermal systems for using heat stored within the earth. Other technologies, many focusing on motor vehicles, harness energy created by mechanical processes. Examples include recovery of vehicle deceleration, which is kinetic energy in the direction of travel; recovery of vehicle shock, which is the upward component of vehicle kinetic energy; and recovery of vehicle wind energy. Still other technologies, such as gray water heat recovery and heat recovery ventilators, focus on recycling the heat used in other operations and/or minimizing waste heat.

Some examples of such technology may use a heat exchanger. A heat exchanger is a device used to transfer heat from a fluid on one side of a barrier to a fluid on the other side of the barrier without bringing the fluids into direct contact. A common example of a heat exchanger is a motor vehicle radiator. The fluids on either side of the barrier may be gas or liquid. A heat exchanger may be used in the production, capture, or consumption of a fuel depending on the technology. For example, a gas liquefaction system, as described below, may use a heat exchanger to absorb heat in order to lower the temperature of a gas. Given its abundance, lack of expense, and relatively high heat capacity, water is often used as one of the fluids in a heat exchanger. At room temperatures, water may absorb a relatively large amount of heat before vaporizing and may continue to absorb heat as a vapor.

As mentioned above, photo-voltaic panels may capture solar energy. A solar concentrator may be used in conjunction with photo-voltaic panels to concentrate sunlight on the panels, thus increasing their efficiency. This energy absorbed by the panels may be converted into several different types of power, including electricity and water-heating means. The market average of photo-voltaic panel efficiency, measured by the energy conversion ratio is about 15%. Thus, the average photo-voltaic panel wastes about 85% of the energy it absorbs as waste heat.

Many technological efforts concerning alternative energy focus on clean motor vehicle fuels with low, or no, emissions. Among this class of technologies are those that use liquefied or solidified hydrogen, nitrogen, carbon dioxide, or other gases as a form of energy storage. Air, which is a combination of 21% oxygen, 78% nitrogen, 0.9% argon, and 0.1% other gases, may also be liquefied or solidified. In a controlled environment, heat appropriately introduced to the system will vaporize the liquefied or solidified gas, producing compressed gas that may aid a pneumatic motor with only the gas itself as exhaust. A pneumatic motor is a machine which converts energy of compressed gas into mechanical work. The liquefied or solidified gas heat sink refrigerant acts as a working fluid coolant to reduce the compression work needed to be performed by the motor compressor, which increases the efficiency of the motor. The liquefied or solidified gas may be referred to as heat sink refrigerant.

Liquefying or solidifying gas requires compression of the gas and/or lowering the temperature of the gas. Thus one method for gas liquefaction or solidification is to expose the gas to something extremely cold that will absorb the heat of the gas, thus lowering the gas's temperature. One example of this method has the gas passing in contact with vessels holding extremely cold water. The cold water will absorb the heat of the gas until the gas condenses or freezes. In this method, waste heat from the process is absorbed by and stored in the water.

Another method for gas liquefaction or solidification uses compression. A standard liquefier or solidifier of such a method operates as follows: Heat of compression is removed from the gas during compression by cooling it to the ambient temperature in a heat exchanger adjacent to the liquefier or solidifier. The gas may be positioned in contact with a solid refrigerant which may cool the gas, thus requiring less compression work. The solid refrigerant may be solid CO₂. The gas is then expanded by venting into a chamber within the liquefier or solidifier. This expansion causes a lowering of the temperature and by counter-flow heat exchange of the expanded air, the pressurized air entering the expander is further cooled. With sufficient compression, flow, and heat removal, eventually droplets of liquefied gas or particles of solidified gas will form, and may be transferred from the liquefier or solidifier into a refrigerant tank. The refrigerant tank is a vacuum storage vessel that provides thermal insulation by interposing a partial vacuum between its contents and the ambient environment, such as a dewar. As explained, the gas liquefaction or solidification process produces waste heat from the removal of heat of compression from the gas. Liquefied or solidified gas may be used to power a low-emission motor vehicle or stationary motor, either directly in a fuel-less engine or indirectly by pre-compression or compression cooling of combustion air to increase engine efficiency. A liquefier or solidifier may be driven by building wind capture, direct wind capture, solar power, and/or a gas turbine, as described in U.S. patent application Ser. No. 12/315,002 to Kaufman, particularly in reference to FIG. 7.

Other methods for gas liquefaction include magnetic refrigerator means, as described in K. Matsumoto, et al, Magnetic refrigerator for hydrogen liquefaction, J. OF PHYSICS: CONFERENCE SERIES 150 (2009), and thermoacoustic Stirling heat engine and refrigerator means, as described in John J. Wollan, et al, Development of a Thermoacoustic Natural Gas Liquefier, Los ALAMOS NAT'L LABORATORY, LA-UR-02-1623 (prepared for presentation at the 2002 AlChE New Orleans Meeting, New Orleans, La., March 11-14).

Gas liquefaction or solidification systems are often used in conjunction with other apparatus. For example, if the system is for liquefaction of pure oxygen or nitrogen, an air separator may be used. Such a device would separate oxygen from compressed air through a pressure swing adsorption process. This process uses a molecular sieve, which attracts nitrogen from air at high pressure and releases it at low pressure. As compressed air passes through the adsorber, the molecular sieve adsorbs nitrogen. This allows the remaining oxygen to pass through and exit the adsorbers as a product gas. Thus, the oxygen and nitrogen in air are separated.

A gas liquefaction or solidification system may also be used in conjunction with a gas turbine with refrigerated compression or pre-compression cooling. A gas turbine with refrigerated compression or pre-compression cooling may store liquid air or nitrogen at temperatures as low as 80K or solidified air or nitrogen at an even lower temperature. In this context, the gas liquefaction or solidification system may supply the refrigerated compression gas turbine with liquefied or solidified product. The liquefied or solidified product is used to cool compressor intake air, reducing compression work from about 50% of turbine output, as with ambient intake, to only about 10%. Gas turbines with refrigerated compression may be stationary or used in a motor vehicle. The power created by the gas turbine with refrigerated compression may be transferred into an electric generator, which may, in turn, power a battery, such as a motor vehicle battery. A stationary refrigerated compression gas turbine may operate during system off-peak times to drive the gas liquefier or solidifier.

When a motor, electric generator, and/or battery is used in conjunction with a gas liquefaction or solidification system, a power conditioner may be included within the system that electrically controls each or all of these elements. The power conditioner may control the flow of power between the system elements with which it is in communication, and to outside elements being powered by the system.

A gas liquefaction or solidification system may also be used in conjunction with a fired heater. The purpose of a fired heater is to add heat to a process fluid, which may provide heat for a chemical reaction. The fluid to which heat may be added may be steam. A fired heater may be used specifically with the heat exchanger portion of a gas liquefaction or solidification system. The heat exchanger may provide a fluid to the fired heater, which may be further heated by the fired heater.

Methanol is commonly used as an alternative to fossil fuels. There are several commonly known methods for methanol synthesis, all of which require a carbon source. One method uses bio-mass for the necessary carbon. Bio-mass is biological material derived from living, or recently living organisms, such as wood, waste, and alcohol fuels. The thermochemical production of methanol from bio-mass involves performing bio-mass pyrolysis to produce a synthesis gas rich in hydrogen (H₂) and carbon monoxide (CO), which is then catalytically converted into methanol (CH₃OH, or MeOH). Production of the synthesis gas is accomplished by thermal gasification.

In one version of the bio-mass method for MeOH synthesis, a fluid bed gasifier is used. The bio-mass may first be dried in a drier. Then the bio-mass is fed into the gasifier and oxygen gas and steam are injected and react with the bio-mass. This bio-mass pyrolysis reaction is endothermic and requires heat to proceed. The synthesis gas exiting the gasifier contains small amounts of impurities, including sulfur and nitrogen, which are then separated in a purifier. The separation also includes the removal of carbon dioxide (CO₂) gas. Although CO₂ reacts with H₂ to produce MeOH (CO₂+3H₂ [symbol] CH₃OH+H₂O), it consumes more H₂ per mole of MeOH formed than the reaction of CO with H₂ to form CH₃OH (CO+2H₂ [symbol] HCH₃OH), thus it is preferable to limit the MeOH synthesis to the CO reaction. This serves the further purpose of consuming CO, which is toxic, as compared to relatively harmless CO₂. The purified synthesis gas is now rich in H₂ and CO, and may react within a synthesis reactor to produce MeOH. In addition to MeOH, the synthesis reactor may also produce tail gas. Tail gas may include unreacted CO and/or H₂. Alternatively, if CO₂ is not eliminated from the synthesis gas during purification, tail gas may also include unreacted CO₂ and/or H₂O.

Methane gas is also often used as a renewable substitute for natural gas. Methanation is the process of generating methane out of a mixture of gases. It is usually performed by a similar process to that described above for methanol synthesis. In methanation, however, the main reaction is CO+3H₂ [symbol] CH₄+H₂O. As the reagents on one side of the reaction are the same as those required of methanol synthesis, whether the reaction produces methane or methanol depends on stoichiometry—controlling the environment of the reaction and the relative quantities of the reagents.

Vapor turbines may be used to harness the thermal and/or kinetic energy of fluids. Examples of vapor turbines in the art include variable speed vapor turbines, such as disclosed in U.S. Pat. No. 3,761,197 to Kelly, and those that include corrosion resistant components for use with corrosive fluids, such as disclosed in U.S. Pat. No. 7,498,087 to Cortese.

### SUMMARY OF THE INVENTION

The present invention is a system for using the waste heat produced from the production of liquefied or solidified heat sink refrigerant in the production of fuel and a method for fuel production using the system. In its most basic form, the system includes a liquefied or solidified heat sink refrigerant production system, a fuel production system, and a heat exchanger. The liquefied or solidified heat sink refrigerant production system produces waste heat which is transferred through the heat exchanger to power the fuel production system.

In a preferred embodiment of the present invention, the system also includes a solar energy capture system. The energy captured from this system may be converted to electricity, which may be used to partly or wholly power the liquefied or solidified heat sink refrigerant production system. The solar energy capture system may also reject waste heat that may be provided to the fuel production system, in addition to the waste heat rejected by the liquefied or solidified heat sink refrigerant production system. The preferred means for transferring heat is one or more heat exchangers or a heat exchanger in combination with a fired heater, such as an ACMA GS Series Steam Superheater. The preferred fuel production system may be a thermal gasification system that produces either methanol or methane.

In a preferred embodiment of the present invention, the liquefied or solidified heat sink refrigerant production system includes a refrigerant cooling phase transformer and a heat exchanger. The refrigerant cooling phase transformer may be a liquefier that liquefies gas or a solidifier that solidifies gas. The system may also include an air separator, a refrigerant tank, a motor, a gas turbine with refrigerated compression, a fired heater, an electric generator, and a power conditioner.

When the refrigerant cooling phase transformer is a liquefier, the liquefier may be the Cosmodyne A400, for example. Nitrogen is the preferred gas liquefied by the liquefier. This nitrogen gas may be supplied to the liquefier by an air separator. The air separator may intake air and separate it into nitrogen and oxygen gases.

The refrigerant cooling phase transformer may deposit the heat sink refrigerant into a refrigerant tank for storage, or directly into a motor to provide compression cooling of working fluid and to support combustion. The refrigerant tank may supply heat sink refrigerant to another system, such as a refrigerant distribution system or a system that consumes heat sink refrigerant, such as a motor vehicle engine. The refrigerant tank may supply refrigerant to a gas turbine with refrigerated compression. The gas turbine with refrigerated compression may include a valve or vent for air intake and may be supplied with tail gas from a fuel synthesis reactor. The gas turbine with refrigerated compression may pass power to an electric generator, which may pass power to a battery, such as a motor vehicle battery. A power conditioner, such as an Atkinson Electronics custom power conditioner, may control the motor and/or the electric generator.

In another preferred embodiment of the present invention, the system includes a solar energy capture system in addition to the liquefied or solidified heat sink refrigerant production system. The energy captured from this system may be converted to electricity, which may be used to partly or wholly power the liquefied or solidified heat sink refrigerant production system. The solar energy capture system may include a solar panel and a heat exchanger. The solar panel is preferably a photo-voltaic panel. The system may also include a power conditioner that controls the photo-voltaic panel. It may also include a solar concentrator to increase the efficiency of the photo-voltaic panel and/or increase the heat that may be supplied to the heat exchanger. The system may be the Spectrolab Solar Cell, for example.

In the preferred embodiment of the present invention, the heat exchanger form part of a liquefied or solidified heat sink refrigerant production system and/or a solar energy capture system, and these heat exchangers may in combination with a fired heater. The heat exchanger may be used so that it may absorb the waste heat rejected from either the liquefier or solidifier in the liquefied or solidified heat sink refrigerant production system, and/or the photo-voltaic panel in the solar energy capture system. The liquid water to which heat is transfer through the heat exchanger preferably turns to steam. A liquid water supply may provide the heat exchanger with liquid water. The heat exchanger may use the waste heat from the liquefied or solidified heat sink refrigerant production system and/or the solar energy capture system to heat the liquid water into steam. The steam from the liquefied or solidified heat sink refrigerant production system's heat exchanger and/or the solar energy capture system's heat exchanger may be provided directly from the heat exchanger(s) to the fuel production system, or the steam may be provided first from the heat exchanger(s) to a fired heater for further heating, and then from the fired heater to the fuel production system. Thus, the heat, in the form of steam, may be supplied to the fuel production system directly or indirectly from the heat exchanger(s).

The fuel production system may be any fuel production system that requires heat to facilitate an endothermic reaction. The preferred embodiment is a thermal gasification system that may produce methanol, methane, or ethanol. It is understood, however, that the fuel production system may be any fuel production system that requires heat to facilitate an endothermic reaction, and that the system may produce any of several small hydrocarbon and hydrocarbon alcohol based fuels.

The basic system may include a gasifier, a purifier, a synthesis reactor, and condensing means, including a vapor turbine and/or a condenser. The system may also include a drier, an electric generator, and a fan. The gasifier may receive the waste heat rejected by the liquefied or solidified heat sink refrigerant production and/or the solar energy capture systems. Thus, in the preferred embodiment, the gasifier may be connected with the heat exchanger(s) and/or the fired heater such that the heat exchanger(s) and/or fired heater may supply the gasifier with steam. Oxygen gas may also be supplied to the gasifier. This oxygen gas may be supplied to the gasifier by an air separator, as described above. A source of carbon, preferably bio-mass, may also be supplied to the gasifier. The bio-mass may have been dried in a drier before being supplied to the gasifier. The thermal gasification system may be the Renugas model from Gas Technology Institute, for example.

Once the reagents are supplied to the gasifier, bio-mass pyrolysis may occur within the gasifier. The heat from the steam may act as the activation energy for the reaction. The synthesis gas product from the gasifier may then be supplied to a purifier, where carbon dioxide may be removed. The purified gas synthesis product from the purifier may then be supplied to a synthesis reactor. The synthesis product gases from the synthesis reactor may include the desired fuel gas and tail gas. When the product gas is methanol, the synthesis reactor may be the Hydro-Chem Methanol Synthesis Reactor, for example. Tail gas may then be supplied back to the gasifier. Tail gas may also be supplied to the fired heater. Tail gas may also be supplied to a gas turbine with refrigerated compression that may be part of the liquefied or solidified heat sink refrigerant production system.

The desired fuel gas is preferably methanol or methane. In the preferred system, the gas may be supplied to a vapor turbine, such as the Barber Coleman Vapor Turbine. The energy harnessed from the vapor turbine may power the electric generator. This electric generator may be controlled by the power conditioner that may be part of the liquefied or solidified heat sink refrigerant production system. Some or all of the desired fuel gas may condense upon being supplied to the vapor turbine to form liquid methanol or methane. Any desired fuel gas not condensed by the vapor turbine may then be supplied to a condenser. A fan with an air vent may aid the condenser. Exhaust from tail gas burned in the fired heater may be supplied to the fan. The condenser may condense the supplied desired fuel gas to produce liquid methanol or methane. In another embodiment of the preferred system, the desired fuel gas may be supplied directly from the synthesis reactor to the condenser. Thus condensing means may include the vapor turbine and the condenser.

Although a thermal gasification system for methanol or methane production is presented as the preferred embodiment of the fuel production system, the present invention contemplates the use of any fuel production system that requires heat to facilitate an endothermic reaction.

Therefore it is an aspect of this invention to provide an improved system and method for producing alternative fuels to fossil fuels.

It is a further aspect of this invention to provide an improved system and method for producing “clean” fuels.

It is a further aspect of this invention to provide an improved system and method for reducing the loss of waste heat in liquefied or solidified heat sink refrigerant production.

It is a further aspect of this invention to provide an improved system and method for reducing the loss of waste heat in solar energy capture systems.

It is a further aspect of this invention to provide an improved system and method for using the waste heat rejected from the production of liquefied or solidified heat sink refrigerant to power the production of fuel.

These aspects of the invention are not meant to be exclusive and other features, aspects, and advantages of the present invention will be readily apparent to those of ordinary skill in the art when read in conjunction with the following description, appended claims, and accompanying figures.

### BRIEF DESCRIPTION OF THE DRAWINGS

FIG. 1 is a diagram of a system, which is a preferred embodiment of the present invention, including a liquefied or solidified heat sink refrigerant system and a thermal gasification system.

FIG. 2 is a diagram of a gas turbine with refrigerant injection to working fluid.

FIG. 3 is a diagram of a gas turbine with recirculated refrigerant cooling of working fluid.

FIG. 4 is a diagram of a system, which is a preferred embodiment of the present invention, including a liquefied or solidified heat sink refrigerant system, a solar energy capture system, and a thermal gasification system.

### DETAILED DESCRIPTION OF THE INVENTION

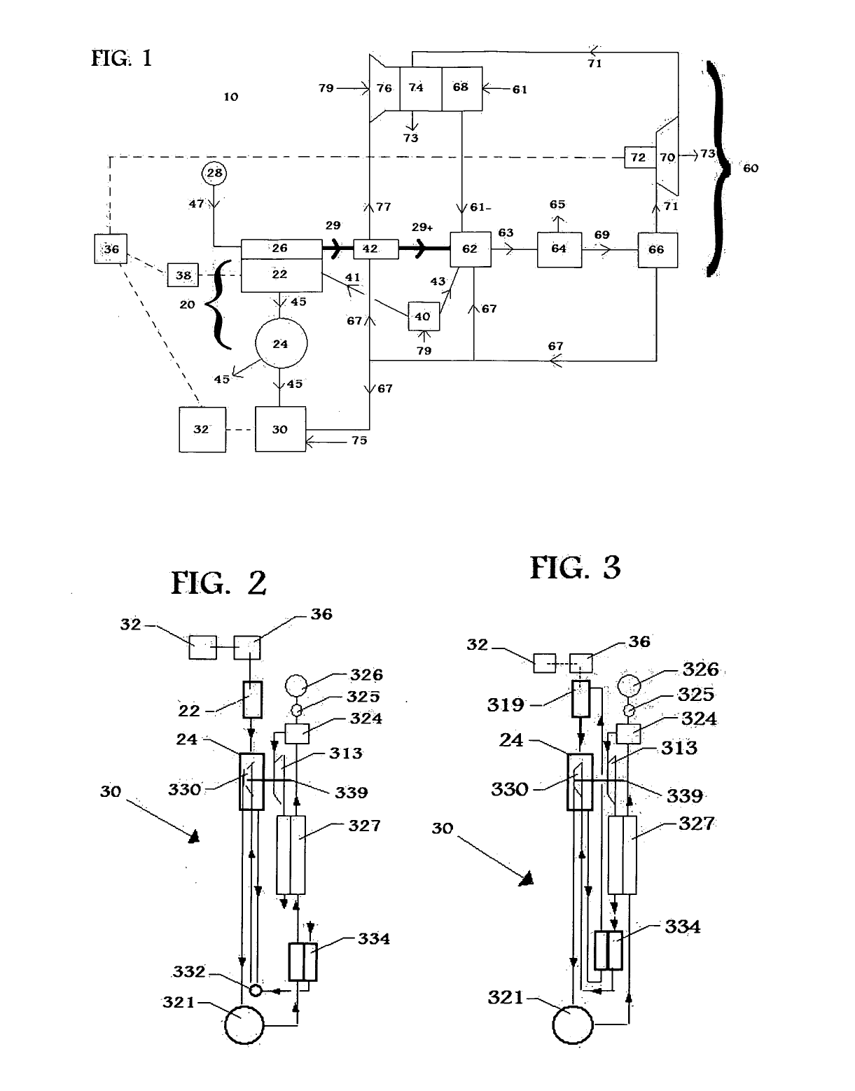

FIG. 1 is a diagram of a preferred system 10 for using the waste heat produced from the production of liquefied or solidified heat sink refrigerant in the production of fuel. Solid, non-emboldened lines represent a gas, a liquid, or a solid. Solid, emboldened lines represent steam. Broken lines represent electricity. All systems or system components are labeled with even numbers. All gases, liquids, or solids that may move between the system components are labeled with odd numbers. In this preferred embodiment, the first fuel production system may be liquefied or solidified heat sink refrigerant production system 20 whose waste heat may power a fuel production system, which may be thermal gasification system 60 for producing methanol 73.

Liquefied or solidified heat sink refrigerant production system 20 may comprise refrigerant cooling phase transformer 22, refrigerant tank 24, heat exchanger 26, liquid water supply 28, gas turbine 30 with refrigerated compression, first generator 32, power conditioner 36, electric motor 38, air separator 40, and fired heater 42. Refrigerant cooling phase transformer 22 may preferably be a liquefier that liquefies gas or a solidifier that solidifies gas. If refrigerant cooling phase transformer 22 is a liquefier, it preferably liquefies nitrogen gas, thus the heat sink refrigerant 45 is liquefied nitrogen. If refrigerant cooling phase transformer 22 is a solidifier, it preferably solidifies carbon dioxide gas, thus the heat sink refrigerant 45 is solidified carbon dioxide. Refrigerant cooling phase transformer 22 may be powered by electric motor 38. Air 79 may be separated into nitrogen 41 and oxygen 43 gases by air separator 40. If refrigerant cooling phase transformer 22 is a liquefier, separator 40 may supply nitrogen gas 41 to refrigerant cooling phase transformer 22. The waste heat rejected by the phase transformation may be absorbed by heat exchanger 26 through liquid water 47 provided to heat exchanger 26 by liquid water supply 28. Although this preferred embodiment includes liquid water supply 28, it is understood that a supply of any liquid that may absorb waste heat rejected by the refrigerant cooling phase transformation such that the liquid will vaporize and may be transferred to thermal gasification system 60 may be used.

Refrigerant cooling phase transformer 22 may provide heat sink refrigerant 45 to refrigerant tank 24 for storage. Refrigerant tank 24 may supply heat sink refrigerant 45 to a system for distribution of refrigerant (not shown) or to a system that uses refrigerant as working fluid coolant to reduce compression work, such as a prime mover of a motor vehicle (not shown). Refrigerant tank 24 may also supply heat sink refrigerant 45 to a gas turbine 30 with refrigerated compression to reduce compression work. Gas turbine 30 with refrigerated compression may comprise an air valve or vent (not shown) for introduction of working fluid air 75 and/or a valve or vent (not shown) for introduction of tail gas 67 from thermal gasification system 60. First electric generator 32 may provide power generated by gas turbine 30 with refrigerated compression. First electric generator 32 may electrically power a battery (not shown). Power conditioner 36 may control electric motor 38, first electric generator 32, and/or a battery.

Waste heat rejected by liquefied or solidified heat sink refrigerant production system 20 and absorbed by heat exchanger 26 may heat liquid water 47 provided to heat exchanger 26 by liquid water supply 28. Heat exchanger 26 may use the waste heat to convert liquid water 47 into steam 29. Steam 29 may be provided to fired heater 42, which may further heat steam 29. Although only heat exchanger 26, and heat exchanger 26 in combination with fired heater 42, are included in this embodiment, it is understood that any means of transferring heat commonly used in the art may be used with the present invention.

Thermal gasification system 60 may comprise drier 68, gasifier 62, purifier 64, methanol synthesis reactor 66, methanol vapor turbine 70, second electric generator 72, condenser 74, and fan 76. Drier 68 may dry bio-mass 61. Drier 68 may provide dried bio-mass 61− (bio-mass 61 minus water/moisture) to gasifier 62. Fired heater 42 may provide steam 29+ (steam 29 plus additional heat) to gasifier 62. Air separator 40 may provide oxygen gas 43 to gasifier 62. Once provided with these reagents, and the heat from steam 29+ for activation energy, gasifier 62 may produce synthesis gas 63 and provide it to purifier 64. Purifier 64 may remove carbon dioxide 65 from synthesis gas 63, and provide purified synthesis gas 69 to methanol synthesis reactor 66. Methanol synthesis reactor 66 may produce methanol gas 71 and tail gas 67. Tail gas 67 may be provided to gasifier 62, fired heater 42, and/or gas turbine 30 with refrigerated compression.

Methanol synthesis reactor 66 may provide methanol gas 71 to methanol vapor turbine 70. Methanol vapor turbine 70 may be powered by the flow of methanol gas 71 from methanol synthesis reactor 66. Methanol vapor turbine 70 may cause some or all of methanol gas 71 to condense into liquid methanol 73. This is one way in which the product of thermal gasification system 60 may be formed. Second electric generator 72 may be controlled by power conditioner 36. Second electric generator 72 may provide or store to a battery (not shown) the power generated from the provision of methanol gas 71 to methanol vapor turbine 70. Any of methanol gas 71 not condensed into liquid by methanol vapor turbine 70 may be provided to condenser 74. Condenser 74 may condense remaining methanol gas 71 into liquid methanol 73. This is another way in which the product of thermal gasification system 60 may be formed. Fan 76 may provide air 79 to condenser 74. Burned exhaust 77 from fired heater 42 may heat air 79 being provided to fan 76. Although only the condensing means of methanol vapor turbine 70 and condenser 74 are included in this embodiment, it is understood that any condensing means commonly used in the art may be used with the present invention.

Although thermal gasification system 60 is presented as the preferred embodiment of the fuel production system of the present invention, it is understood that any fuel production system that requires heat to facilitate an endothermic reaction may be used. Moreover, although methanol is presented as the desired fuel product of the fuel production system, it is understood that the desired fuel product may be any of several hydrocarbon or hydrocarbon alcohol based fuels, such as methane and ethanol.

FIG. 2 is a diagram of a gas turbine 30 with working fluid cooling by injection of heat sink refrigerant. This rendering represents a preferred embodiment of the gas turbine 30 with refrigerated compression of liquefied or solidified heat sink refrigerant production system 20. In this embodiment, refrigerant cooling phase transformer 22 is a liquefier, thus the heat sink refrigerant 45 produced is liquid. In addition to the refrigerant cooling phase transformer 22, first electric generator 32, power conditioner 36, and refrigerant tank 24 are common elements between FIGS. 1 and 2. In this embodiment, the heat sink refrigerant 45 is injected into the working fluid, and becomes a part of the working fluid, as opposed to remaining a heat sink refrigerant as shown in FIG. 3.

Electrical power from first electric generator 32 during off-peak operation of gas turbine 30 with refrigerated compression, may be supplied to power conditioner 36, which may combine the varying power from first electric generator 32 into a stable power output. Refrigerant cooling phase transformer/liquefier 22 may produce waste heat that may be captured and used for fuel production, as described in reference to FIG. 1. In some embodiments, power conditioner 36 may include a rheostat and an inverter, which may convert the direct current electrical power into alternating current. In others, it may include a deep current battery that may accept the various power inputs and may provide a constant direct current output. The power conditioner 36 may provide power to refrigerant cooling phase transformer/liquefier 22 which may take in nitrogen gas from separator 40 (shown in FIG. 1), liquefy the nitrogen gas, and supply liquefied heat sink refrigerant 45 to a refrigerant tank 24. Although nitrogen is presented as the preferred gas for liquefaction, it is understood that other pure and composite gases, such as hydrogen and air, may also be used for liquefaction. Refrigerant tank 24 is preferably a dewar, or other cryogenic tank that may maintain the liquefied heat sink refrigerant 45 in a liquid state. Liquefied heat sink refrigerant 45 from the refrigerant storage tank 24 may be used in other applications, such as vehicle operation.

Liquefied heat sink refrigerant 45 may flow from the refrigerant tank 24 into mixing tank 332, where the liquefied heat sink refrigerant 45 may be mixed with atmospheric air from chiller 334 to form vaporized liquid nitrogen. The vaporized liquid air may then pass into compressor 330. Compressor 330 may be enclosed within refrigerant tank 24. Compressor 330 may act to heat and compress a mixture of liquefied heat sink refrigerant 45 and atmospheric air such that the liquefied heat sink refrigerant 45 may change phase and the mixture of liquefied heat sink refrigerant 45 and atmospheric air may turn into compressed air. This compressed air may then flow into compressed working fluid tank 321.

Compressed air from compressed working fluid tank 321 may flow through the chiller 334, which may be a counter flow heat exchanger that allows heat from the atmospheric air to be transferred to the compressed air. The compressed air may then flow through recuperator 327, which may also be a counter flow heat exchanger that allows heat from the exhaust gasses from the turbine 313 to be transferred to the compressed air. The heated compressed air may then pass into combustor 324, where it may serve as combustion air for fuel pumped by fuel pump 325 from fuel tank 326. Combustion gasses may then pass from combustor 324 into turbine 313, causing turbine 313 to rotate. This rotation may act to rotate shaft 339, which may provide motive power to compressor 330. Exhaust gas heat may be recovered by recuperator 327 and exhaust may continue to the atmosphere.

FIG. 3 is a diagram of a gas turbine with working fluid cooling by recirculation of refrigerant. This rendering represents another preferred embodiment of the gas turbine 30 with refrigerated compression of liquefied or solidified heat sink refrigerant production system 20, as in FIG. 1. In this embodiment, refrigerant cooling phase transformer 22 is a solidifier, thus the heat sink refrigerant 45 produced is solid. In addition to the refrigerant cooling phase transformer 22, first electric generator 32, power conditioner 36, and refrigerant tank 24 are common elements between FIGS. 1 and 3. In this embodiment, the liquefied or sublimated refrigerant is circulated through a heat sink exchanger and thus remains a heat sink refrigerant, as opposed to becoming part of the working fluid as shown in FIG. 2.

FIG. 3 differs from FIG. 2 in that it includes a closed loop between refrigerant cooling phase transformer/solidifier 22, refrigerant tank 24, and chiller 334, and lacks mixing tank 332. In this embodiment, refrigerant cooling phase transformer/solidifier 22 provides solidified heat sink refrigerant 45 to refrigerant tank 24 which melts in contact with compressor 330 such that atmospheric air passing through chiller 334 will be cooled by liquid or gaseous refrigerant before being provided to compressor 330. The solidified heat sink refrigerant 45 may be solid CO2. The CO2 from chiller 334 is continuously resolidified by refrigerant cooling phase transformer/solidifier 22

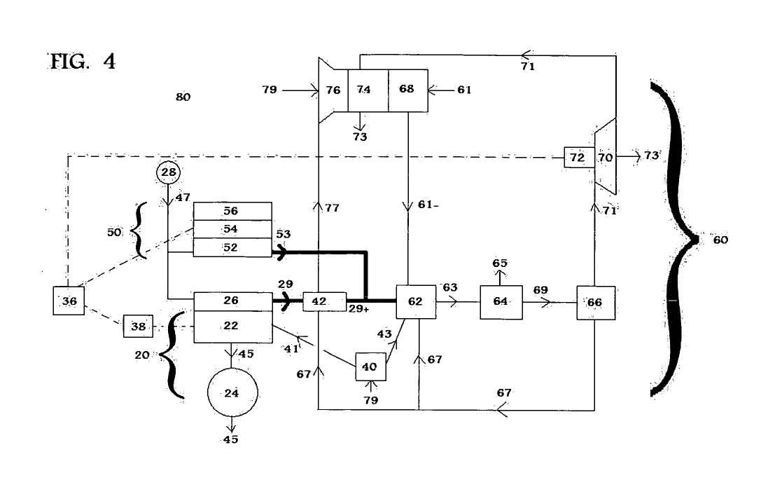

FIG. 4 is a diagram of a preferred system 80 for using the waste heat produced from the production of liquefied or solidified heat sink refrigerant in the production of fuel, where liquefied or solidified heat sink refrigerant production system 20 is partly or wholly powered by solar energy capture system 50. Solid, non-emboldened lines represent a gas, a liquid, or a solid. Solid, emboldened lines represent steam. Broken lines represent electricity. All systems or system components are labeled with even numbers. All gases, liquids, or solids that may move between the system components are labeled with odd numbers. Waste heat from liquefied or solidified heat sink refrigerant production system 20 and solar energy capture system 50 may power a fuel production system, which may be thermal gasification system 60 for producing methanol 73.

Liquefied or solidified heat sink refrigerant production system 20 may comprise refrigerant cooling phase transformer 22, refrigerant tank 24, first heat exchanger 26, liquid water supply 28, power conditioner 36, electric motor 38, air separator 40, and fired heater 42. Refrigerant cooling phase transformer 22 may preferably be a liquefier that liquefies gas or a solidifier that solidifies gas. If refrigerant cooling phase transformer 22 is a liquefier, it preferably liquefies nitrogen gas, thus the heat sink refrigerant 45 is liquefied nitrogen. If refrigerant cooling phase transformer 22 is a solidifier, it preferably solidifies carbon dioxide gas, thus the heat sink refrigerant 45 is solidified carbon dioxide. Refrigerant cooling phase transformer 22 may be powered by electric motor 38. Air 79 may be separated into nitrogen 41 and oxygen 43 gases by air separator 40. If refrigerant cooling phase transformer 22 is a liquefier, separator 40 may supply nitrogen gas 41 to refrigerant cooling phase transformer 22. The waste heat rejected by the phase transformation may be absorbed by heat exchanger 26 through liquid water 47 provided to heat exchanger 26 by liquid water supply 28.

Refrigerant cooling phase transformer 22 may provide heat sink refrigerant 45 to refrigerant tank 24 for storage. Refrigerant tank 24 may supply heat sink refrigerant 45 to a system for distribution of refrigerant (not shown) or to a system that consumes refrigerant as coolant to reduce compression work, such as a prime mover of a motor vehicle (not shown).

Waste heat rejected by liquefied or solidified heat sink refrigerant production system 20 and absorbed by first heat exchanger 26 may heat liquid water 47 provided to first heat exchanger 26 by liquid water supply 28. First heat exchanger 26 may use the waste heat to convert liquid water 47 into first steam 29. First steam 29 may be provided to fired heater 42, which may further heat first steam 29.

Solar energy capture system 50 may comprise second heat exchanger 52, photo-voltaic panel 54, solar concentrator 56, liquid water supply 28, and power conditioner 36. Photo-voltaic panel 54 may absorb sunlight. Solar concentrator 56 may concentrate sunlight on photo-voltaic panel 54 to increase the efficiency of photo-voltaic panel 54 and increase the amount of heat that may be provided to second heat exchanger 52. The sunlight absorbed by photo-voltaic panel 54 may be converted to electricity, which may be controlled by power conditioner 36, and provided to liquefied or solidified heat sink refrigerant production system 20 to power electric motor 38. Any waste heat absorbed by photo-voltaic panel 54, but not converted into electricity may be absorbed by second heat exchanger 52 through liquid water 47 provided to second heat exchanger 52 by liquid water supply 28.

Waste heat rejected by solar energy capture system 50 and absorbed by second heat exchanger 52 may heat liquid water 47 provided to second heat exchanger 52 by liquid water supply 28. Heat exchanger 52 may use the waste heat to convert liquid water 47 into second steam 53. In some embodiments, second steam 53 may be further heated by a fired heater. Although only heat exchanger 26, heat exchanger 26 in combination with fired heater 42, and heat exchanger 52 are included in this embodiment, it is understood that any heat transfer means commonly used in the art may be used with the present invention.

Thermal gasification system 60 comprises drier 68, gasifier 62, purifier 64, methanol synthesis reactor 66, methanol vapor turbine 70, electric generator 72, condenser 74, and fan 76. Drier 68 may dry bio-mass 61. Drier 68 may provide dried bio-mass 61− (bio-mass 61 minus water/moisture) to gasifier 62. Fired heater 42 may provide first steam 29+ (first steam plus additional heat) to gasifier 62. Second heat exchanger 52 may provide second steam 53 to gasifier 62. Air separator 40 may provide oxygen gas 43 to gasifier 62. Once provided with these reagents, and the heat from first steam 29+ and second steam 53 for activation energy, bio-mass pyrolysis may occur within gasifier 62 and may produce synthesis gas 63, which may be provided to purifier 64. Purifier 64 may remove carbon dioxide 65 from synthesis gas 63, and provide purified synthesis gas 69 to methanol synthesis reactor 66. Methanol synthesis reactor 66 may produce methanol gas 71 and tail gas 67. Tail gas 67 may be provided to gasifier 62 and/or fired heater 42.

Methanol synthesis reactor 66 may provide methanol gas 71 to methanol vapor turbine 70. Methanol vapor turbine 70 may be powered by the flow of methanol gas 71 from methanol synthesis reactor 66. Methanol vapor turbine 70 may cause some or all of methanol gas 71 to condense into liquid methanol 73. This is one way in which the product of thermal gasification system 60 may be formed. Electric generator 72 may be controlled by power conditioner 36. Electric generator 72 may provide or store in a battery (not shown) the power generated from the provision of methanol gas 71 to methanol vapor turbine 70. Any of methanol gas 71 not condensed by methanol vapor turbine 70 may be provided to condenser 74. Condenser 74 may condense remaining methanol gas 71 into liquid methanol 73. This is another way in which the product of thermal gasification system 60 may be formed. Fan 76 may provide air 79 to condenser 74. Burned exhaust 77 from fired heater 42 may heat air 79 to fan 76. Although only the condensing means of methanol vapor turbine 70 and condenser 74 are included in this embodiment, it is understood that any condensing means commonly used in the art may be used with the present invention.

Although the present invention has been described in considerable detail with reference to certain versions thereof, other versions would be readily apparent to those of ordinary skill in the art. Therefore, the spirit and scope of the appended claims should not be limited to the description of the preferred versions contained herein.

1. A system for using waste heat comprising:
a refrigerant cooling phase transformation system comprising:
a refrigerant cooling phase transformer that produces a first waste heat; and
a first heat exchanger in communication with said refrigerant cooling phase transformer, wherein said first heat exchanger is dimensioned to absorb said first waste heat from said refrigerant cooling phase transformer; and
a fuel production system in thermal communication with said first waste heat from said first heat exchanger, said fuel production system comprising a chemical process means for producing a fuel using an endothermic reaction;
wherein said first waste heat from said first heat exchanger is used as activation energy for said endothermic reaction.

2. The system as claimed in claim 1 wherein said refrigerant cooling phase transformer is selected from the group consisting of a gas liquefier and a fluid solidifier.

3. The system as claimed in claim 1 wherein said refrigerant cooling phase transformer further comprises a first liquid water supply in communication with said first heat exchanger such that said first liquid water supply supplies a first liquid water to said heat exchanger; and
wherein said first heat exchanger is dimensioned to transfer said first waste heat to said first liquid water.

4. The system as claimed in claim 3 wherein said first heat exchanger is dimensioned to transfer said first waste heat to said first liquid water such that said first liquid water changes phase to become a first steam.

5. The system as claimed in claim 3 further comprising a solar energy capture system comprising:
a solar panel that produces a second waste heat;
a second heat exchanger in communication with said solar panel such that said second heat exchanger absorbs said second waste heat; and
a second liquid water supply in communication with said second heat exchanger such that said second liquid water supply supplies a second liquid water to said second heat exchanger; and
wherein said second heat exchanger is in fluid communication with said first heat exchanger and said fuel production system such that said first waste heat and said second waste heat are combined to form a combined waste heat and such that said combined waste heat is used as activation energy for said endothermic reaction.

6. The system as claimed in claim 5 wherein said solar panel is a photo-voltaic panel that produces electricity and wherein electricity produced by said photo-voltaic panel is in electrical communication with said refrigerant cooling phase transformation system.

7. The system as claimed in claim 5 further comprising a fired heater in fluid communication with at least one of said first heat exchanger and said second heat exchanger;
wherein said first heat exchanger is dimensioned to transfer said first waste heat to said first liquid water such that said first liquid water changes phase to become a first steam;
wherein said second heat exchanger is dimensioned to transfer said second waste heat to said second liquid water such that said second liquid water changes phase to become a second steam; and
wherein said fired heater is dimensioned to transfer additional heat to at least one of said first steam and said second steam.

8. The system as claimed in claim 1 wherein said chemical process means of said fuel production system comprises:
a source of carbon;
a source of oxygen;
a gasifier in communication with said source of carbon and said source of oxygen, and in thermal communication with said first waste heat, wherein said gasifier is dimensioned and arranged to produce a synthesis gas product using said first waste heat as activation energy for said endothermic reaction;
a purifier in communication with said gasifier such that said synthesis gas product of said gasifier is supplied to said purifier, wherein said purifier is dimensioned and arranged to produce a purified synthesis gas product;
a synthesis reactor in communication with said purifier such that said purified synthesis gas product of said purifier is supplied to said synthesis reactor, wherein said synthesis reactor is dimensioned and arranged to produce said fuel in a gaseous state from said purified synthesis gas product; and
at least one condensing means for condensing fuel from a gaseous state into a liquid state, wherein said condensing means is in fluid communication with said synthesis reactor.

9. The system as claimed in claim 8 wherein said fuel production system produces said fuel selected from a group consisting of methanol, methane, and ethanol.

10. The system as claimed in claim 8 wherein said source of carbon is a bio-mass.

11. The system as claimed in claim 5 wherein said chemical process means of said fuel production system comprises:
a source of carbon;
a source of oxygen;
a gasifier in communication with said source of carbon and said source of oxygen, and in thermal communication with said combined waste heat, wherein said gasifier is dimensioned and arranged to produce a synthesis gas product using said combined waste heat as activation energy for said endothermic reaction;
a purifier in communication with said gasifier such that said synthesis gas product of said gasifier is supplied to said purifier, wherein said purifier is dimensioned and arranged to produce a purified synthesis gas product;
a synthesis reactor in communication with said purifier such that said purified synthesis gas product of said purifier is supplied to said synthesis reactor, wherein said synthesis reactor is dimensioned and arranged to produce said fuel in a gaseous state from said purified synthesis gas product; and
a condenser in fluid communication with said synthesis reactor, wherein said condenser is dimensioned and arranged to condense said fuel from a gaseous state into a liquid state.

12. A system for using waste heat comprising:
a liquefied refrigerant heat sink production system comprising:
a gas liquefier that produces a waste heat; and
a heat exchanger in communication with said gas liquefier such that said heat exchanger absorbs said waste heat produced by said gas liquefier; and
a fuel production system in thermal communication with said waste heat from said heat exchanger of said liquefied refrigerant heat sink production system, wherein said fuel production system comprises means for using said waste heat to produce a fuel.

13. The system as claimed in claim 12 wherein said fuel production system is a thermal gasification system.

14. A system for using waste heat comprising:
a solidified refrigerant heat sink production system comprising:
a fluid solidifier that solidifies a refrigerant and produces a waste heat; and
a heat exchanger in communication with said fluid solidifier such that said heat exchanger absorbs said waste heat produced by said fluid solidifier; and
a fuel production system in thermal communication with said waste heat from said heat exchanger of said solidified refrigerant heat sink production system, wherein said fuel production system comprises means for using said waste heat to produce a fuel.

15. The system as claimed in claim 14 wherein said fuel production system is a thermal gasification system.

16. The system as claimed in claim 14 further comprising a gas turbine in communication with a source of a working fluid, wherein gas turbine comprises a working fluid compressor, wherein said working fluid is atmospheric air, and wherein said fluid solidifier is dimensioned and arranged such that said solidified refrigerant cools said atmospheric air entering said working fluid compressor of said gas turbine.

17. The system as claimed in claim 16 further comprising a chiller in communication with said atmospheric air, wherein one of a liquid refrigerant melted from said solidified refrigerant and gaseous refrigerant sublimated from said solidified refrigerant is in communication with and cools said chiller, and wherein said chiller cools said atmospheric air entering said working fluid compressor of said gas turbine.

18. A method for using waste heat from a refrigerant cooling phase transformation system as activation energy for a fuel production system that uses an endothermic reaction to produce a fuel, said method comprising the steps of:
removing said waste heat from a refrigerant;
transferring said waste heat to a fluid to produce a heated fluid;
providing said heated fluid to said fuel production system; and
transferring said waste heat from said heated fluid to said fuel production system to activate an endothermic reaction; and
producing a fuel through said endothermic reaction within said fuel production system.

19. The method as claimed in claim 18 wherein said step of transferring said waste heat to a fluid comprises the step of transferring said waste heat to a fluid to produce a heated fluid in vapor form.

20. The method as claimed in claim 18 wherein said step of transferring said waste heat from said heated fluid to said fuel production system to activate an endothermic reaction comprises the step of transferring said waste heat from said heated fluid in vapor form to said fuel production system to activate an endothermic reaction.
